(19) United States
(12) Patent Application Publication
(10) Pub. No.: US 2014/0130844 A1
(43) Pub. Date: May 15, 2014

(54) SOLAR POWER GENERATOR

(71) Applicant: KABUSHIKI KAISHA TOSHIBA, Tokyo (JP)

(72) Inventors: Ryosuke YAGI, Kanagawa (JP); Norihiro TOMIMATSU, Tokyo (JP); Toshiro HIRAOKA, Kanagawa (JP)

(73) Assignee: KABUSHIKI KAISHA TOSHIBA, Tokyo (JP)

(21) Appl. No.: 14/079,082

(22) Filed: Nov. 13, 2013

(30) Foreign Application Priority Data
Nov. 14, 2012 (JP) 2012-250618

(51) Int. Cl. H01L 31/052

(52) U.S. Cl. CPC H01L 31/052
USPC 136/246

(57) ABSTRACT

A solar power generator of an embodiment includes: a solar cell module having a solar cell, and a heat storage material filled unit configured to house a heat storage material disposed so as to thermally contact a back surface side of the solar cell, and a nucleating unit configured to release supercooling of the heat storage material; and a controller configured to control the nucleating unit.

### CROSS-REFERENCE TO RELATED APPLICATION

This application is based upon and claims the benefit of priority from Japanese Patent Applications No. 2012-250618 Nov. 14, 2012; the entire contents of which are incorporated herein by reference.

### FIELD

Embodiments described herein relate generally to a solar power generator.

### BACKGROUND

A problem with a solar cell is that a power generation efficiency decreases with a rise in a cell temperature.

In particular, since the cell temperature rises during the daytime in summer, when an electric power demand is the highest, there have been several proposals made to improve the power generation efficiency by cooling the cell temperature.

Therefore, as a method of decreasing the cell temperature, there has been known a method of absorbing heat of the cell by a latent heat storage material. The cell temperature becomes very high in a region where an amount of solar radiation is high and an outside air temperature is high, and heat storage from the cell to the heat storage material progresses in a short period of time, whereby the heat storage material may be completely melted during the daytime and may reach a temperature equal to or higher than a melting point thereof. In such a case, there was a problem in that latent heat of solidification is released from the heat storage material to the cell over a long period of time during a process where the temperature of the heat storage material decreases from the temperature equal to or higher than the melting point to a temperature equal to or lower than the melting point, and the temperature of the solar cell is kept high in the evening before sunset, whereby the amount of power generation is decreased.

### BRIEF DESCRIPTION OF THE DRAWINGS

FIG. 1 is a conceptual diagram of a solar power generator according to an embodiment;

FIG. 2 is a flowchart illustrating operation of the solar power generator according to an embodiment;

FIG. 3 is a graph illustrating a relationship between an amount of power generated by the solar cell by the time and a temperature change according to an embodiment;

FIG. 4 is a flowchart illustrating operation of the solar power generator according to an embodiment;

FIG. 5 is a conceptual diagram of the solar power generator according to an embodiment; and

FIG. 6 is a flowchart illustrating operation of the solar power generator according to an embodiment.

### DETAILED DESCRIPTION

A solar power generator of an embodiment includes: a solar cell module having a solar cell, and a heat storage material filled unit configured to house a heat storage material disposed so as to thermally contact a back surface side of the solar cell, and a nucleating unit configured to release supercooling of the heat storage material; and a controller configured to control the nucleating unit.

Embodiments will be described below with reference to the drawings.

Hereinafter, embodiments will be exemplified with reference to the drawings. Note that detailed descriptions common to the embodiments will be omitted as appropriate. Also note that daytime, evening, and night below are expressions according to an amount of solar radiation under a clear sky, and are not expressions for limiting a period of time.

### First Embodiment

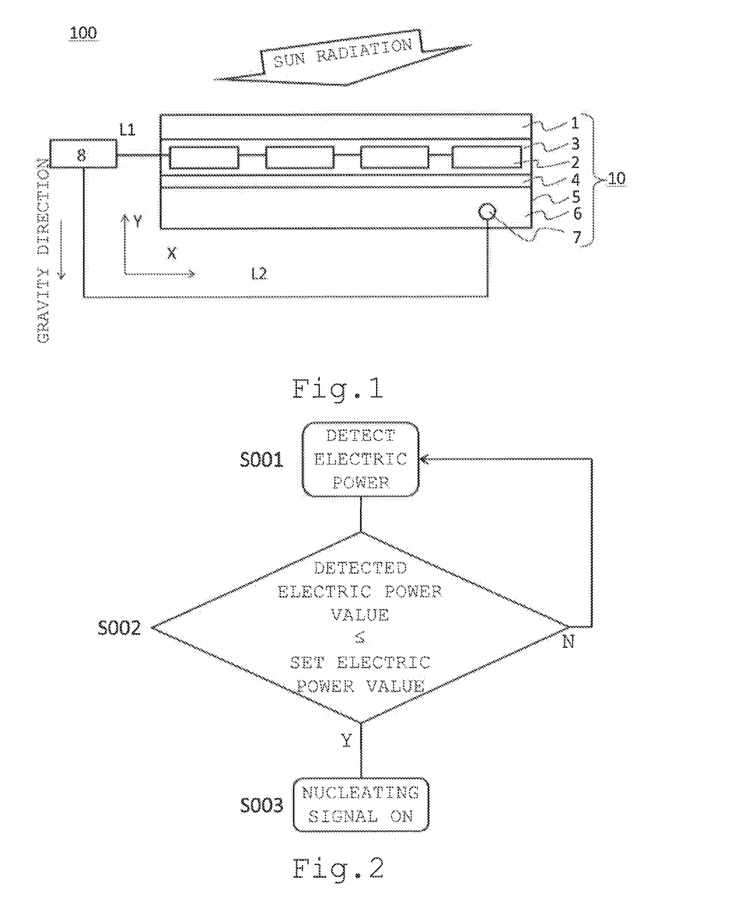

FIG. 1 is a conceptual diagram of a solar power generator 100 according to a first embodiment. The solar power generator 100 according to FIG. 1 includes a solar cell module 10 having a glass plate 1, a solar cell 2, a sealing material 3, a heat exchanger plate 4, a hear storage material filled unit 5, a heat storage material 6, and a nucleating unit 7, and a controller 8. Therefore, in this configuration, heat from the solar cell 2 is transmitted to the heat storage material 6 through the sealing material 3, the heat exchanger plate 4, and the heat storage material filled unit 5. A direction opposite to gravity is a Y-axis, and a direction vertical to the Y-axis is an X-axis.

The glass plate 1 is a plate serving as a protection layer of a surface of the solar cell 2. A low reflectivity glass plate is preferable as the glass plate 1.

The solar cell 2 generates power by converting sunlight, which enters through the glass plate 1, into electricity. The solar cell module 10 is provided with a plurality of solar cells 2, and each of the solar cells 2 is electrically connected with each other. A photoelectric conversion element of the solar cells 2 is net particularly limited. Various photoelectric conversion elements such as a silicon type, a compound type, an organic type, a quantum dot type, and a multi-junction type may be used.

The sealing material 3 seals the solar cells 2 and attaches the solar cells 2 to the glass plate 1. As the sealing material 3, EVA (polyethylene vinyl acetate) and the like may be used, for example. In FIG. 1, the sealing material 3 is also included between the solar cells 2; however, it is also possible to sandwich the solar cells 2 with a sheet-like sealing material 3.

The heat exchanger plate 4 is formed on a back surface side of the solar cells 2. The heat exchanger plate 4 is a member that efficiently transmits the heat from the solar cells 2 to the heat storage material 6 inside the heat storage material filled unit 5. As the heat exchanger plate 4, a metal plate or a resin sheet may be used. The hear exchanger plate 4 may function as an adhesive layer for adhering the sealing material 3 and the heat storage material filled unit 5. It is also possible to omit it in a case where it is replaceable by the sealing material 3.

The heat storage material filled unit 5 is formed so as to thermally contact the back surface side of the solar cells 2. The heat storage material filled unit 5 includes a heat storage material 6 and a nucleating unit 7 therein. A housing of the heat storage material filled unit 5 may be a resin container, a metal container, a metal-resin compound container, or a bag having a film made of any of these materials. It is preferable that a member capable of following a volume change of the heat storage material 6 accompanied by solidification and melting thereof be used as the heat storage material filled unit 5.

The heat storage material 6 collects, stores, and releases the heat from the solar cells 2. It is preferable that a latent heat storage material having a melting point thereof in a range between an ordinary temperature (20°C.) and 100°C. and having a supercooling state be used. The latent heat storage material having the supercooling is a material that does not solidify by once heating in a the temperature of equal or higher than the melting point and cooling in a temperature of lower than the melting point and existing in a liquid phase in a room temperature (20°C.) which is lower than the melting point. As the latent heat storage material having the supercooling, a sodium sulfate hydrate, a sodium acetate hydrate, an erythritol, and the like may be used. These heat storage materials have a melting point in a range between 30 and 90°C., and also have a supercooling state in about 20°C. which is a lower temperature than the melting point.

The nucleating unit 7 partially contacts with the heat storage material 6, and functions to solidify (crystallize) the heat storage material 6 in a supercooled state. A specific nucleating method used may be a method of inserting two electrodes and applying a voltage between the electrodes, a method of moving a plate spring by an actuator in a configuration including the plate spring having a recess and a projection and the actuator, and a method of applying a voltage to a thermoelectric element for local rapid cooling, a method of nucleating by inputting a crystal nucleus from a crystal nucleus housing container, and the like.

The controller 8 is connected to the solar cells 2 through a wiring L1 and to the nucleating unit 7 through a wiring L2. The controller 8 has an electronic circuit including an integrated circuit, and is controlled by hardware or software. An operation condition of the nucleating unit 7 is memorized in the controller 8. Electric power generated by the solar cells 2 is transmitted to the controller 8 through the wiring L1. Accordingly, the controller 8 measures an amount of electric power generated by a cell. Furthermore, an operation instruction of the nucleating unit 7 is transmitted from the controller 8 to the nucleating unit 7 through the wiring L2. The controller 8 may be included inside the solar cell module 10 or may be included inside a device outside the solar cell module 10 such as a power conditioner and the like.

Furthermore, by installing the heat exchanger plate 4, the heat storage material filled unit 5, the heat storage material 6, and the nucleating unit 7 according to the embodiment on a back surface of an existing solar cell module, it is possible to modify the existing solar cell module to be a solar cell module or a solar power generator according to the embodiment.

Next, an operation of the solar power generator (solar power generation system) according to the embodiment is described. The operation of the solar power generator according to the embodiment is controlled by the above-described controller 8. FIG. 2 is a flowchart illustrating a method of operating the solar power generator 100. This flowchart is recorded in advance in the controller 8, which operates each device based on a condition therein through the wiring L1 and the wiring L2. Note that at the time of Step S001, the heat storage material 6 has collected the heat from the solar cells 2 and is in a supercooled state.

In the flowchart in FIG. 2, first, the controller 8 measures the electric power generated by the solar cell 2 through the wiring L1 (electric power detecting: Step S001). Then, determination is performed by comparing the measured electric power (detected electric power value) and a predetermined set electric power (set electric power value) (Step S002). Then, in a case where the measured electric power is equal to or lower than the predetermined set electric power, a nucleating signal is given to the nucleating unit 7 through the wiring L2. Accordingly, the heat storage material 6, which has stored the heat and is kept in the supercooled state, is crystallized, and latent heat is released. In the electric power determination in Step S002, in addition to an instantaneous value of the measured electric power, an hourly average electric power in several minutes or several hours, an electric power variation per unit time, and the like may be used. Note that in a case where the measured electric power is larger than the predetermined set electric power, the electric power is measured again (Step S001).

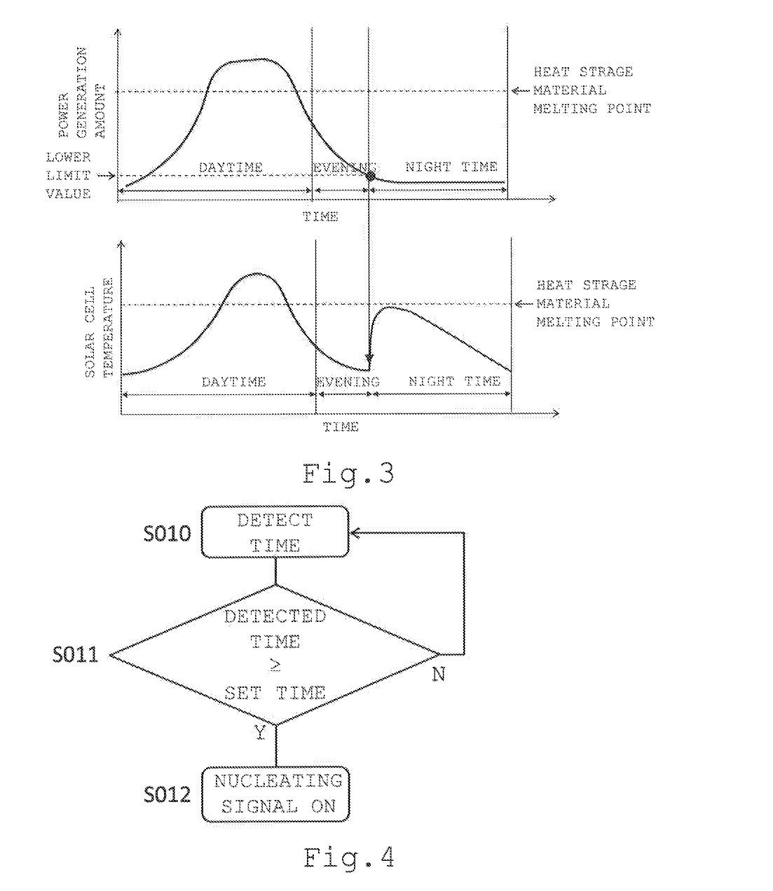

FIG. 3 is a graph illustrating a relationship between an amount of power generation by the time and a temperature change of the solar cells 2 when the solar power generator 100 is operated based on the flowchart in FIG. 2.

During the daytime (from morning to late afternoon), which is a period of time when the amount of solar radiation is large, the solar cell 2 generates power and absorbs solar heat, whereby the temperature thereof rises. Since the heat storage material 6 is thermally in contact with the solar cells 2, the heat from the solar cells 2 is stored in the heat storage material 6 due to a difference in temperatures between the solar cells 2 and the heat storage material 6. Accordingly, a rise in the temperature of the solar cells 2 is suppressed, whereby it is possible to suppress a decrease in the amount of power generation accompanied by the rise in the temperature of the solar cells 2. With the time, absorption of heat from the solar cells 2 to the heat storage material 6 progresses, and when the heat storage material 6 reaches the melting point or above, the heat storage material 6 melts from solid to liquid (in the daytime domain and with a large amount of solar radiation).

Then, the temperature of the solar cells 2 decreases as the amount of solar radiation decreases when it nears the sunset and the like. At this time, even if the temperature of the heat storage material 6 reaches the melting point thereof or below, the heat storage material 6 keeps the supercooling. Therefore, a temperature of the heat storage material 6, without being kept at the melting point, decreases without releasing the latent heat of solidification. Therefore, since there is no release of heat from the heat storage material 6, the temperature of the solar cells 2 decreases, and it is possible to suppress the decrease in the amount of power generation with the temperature (in the evening domain with a low amount of solar radiation).

During nighttime, since there is no solar radiation from the sun, the temperature of the solar cells 2 further decreases, and nears an atmospheric temperature. Therefore, an hour during which the amount of power generation drops below a predetermined set electric power value is determined as the nighttime, whereby the supercooled heat storage material 6 is nucleated, and the heat is radiated at the time when the amount of power generation drops below a lower limit electric power value (in the nighttime domain with no solar radiation). Since there is almost no power generation during the nighttime, the amount of power generation is not decreased even as a result of the rise in the temperature accompanied by radiation of heat. On the other hand, by radiating the latent heat of the heat storage material 6 during the nighttime, even in a case where the heat storage material 6 exceeds the melting point in the evening, the latent heat is not released in a process in which the temperature equal to or lower than the melting point decreases, whereby it is possible to decrease the temperature of the solar cell 2.

### Second Embodiment

FIG. 4 is a flowchart illustrating a method of operating a solar power generator 100 (solar power generation system) by the time.

In the first embodiment, the amount of power generated by a solar cells 2 is measured, and the nucleating signal is operated based on the value; however, in this embodiment, it is possible to operate the nucleating signal by measuring the nighttime, during which a power generation period (daytime and evening) ends, based on the time. A measured time is the time of a clock incorporated in a controller 8 or the time obtained by the controller 8 from an outside device.

First, the controller 8 measures the time (time detecting: Step S010). Then, the measured time (detected time) and a predetermined set time are compared to perform determination (Step S011). Then, in a case where the measured time is the same as or has passed the predetermined set time, a nucleating signal is given to a nucleating unit through a wiring L2 (from. Step S011 to Step S012). Accordingly, a heat storage material 6, which has stored heat and is kept in a supercooled state, is crystallized, and latent heat is released. In this method, by setting the set time to nighttime, it is possible to cause the heat storage material 6 to nucleate and to radiate heat during the nighttime. In a case where the measured time is before the predetermined set time, the time is measured again (Step S011).

### Third Embodiment

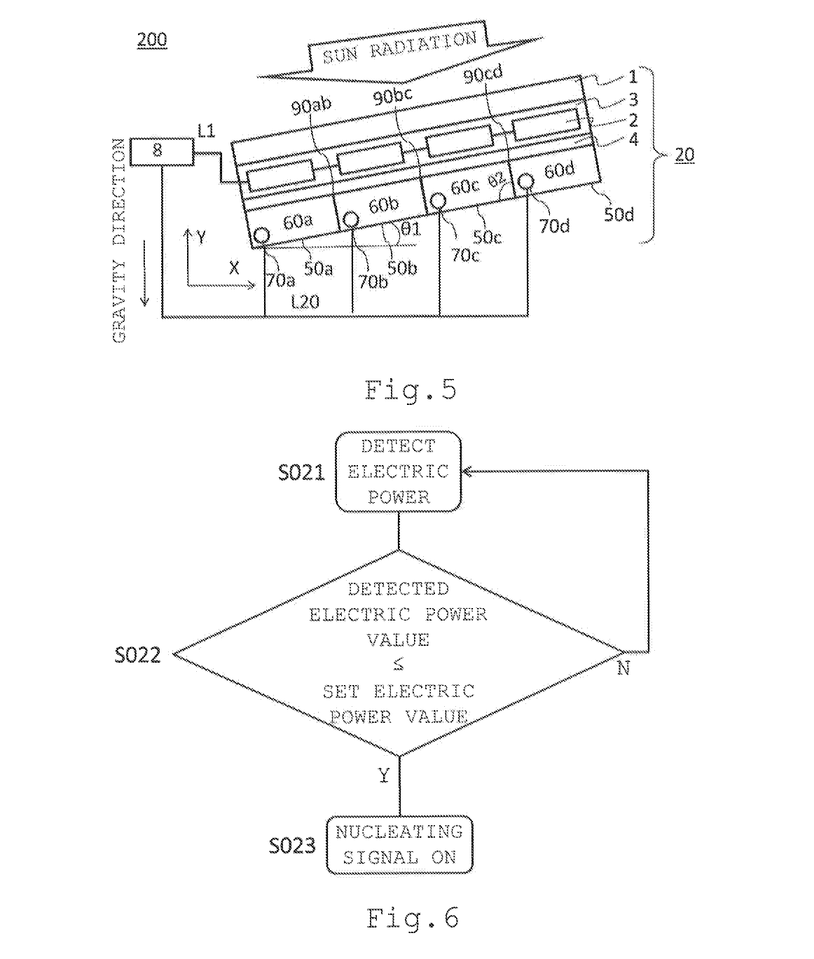

FIG. 5 is a schematic view of a solar power generator 200 according to a third embodiment. The solar power generator 200 includes a solar cell module 20 having a glass plate 1, a solar cell 2, a sealing material 3, a heat exchanger plate 4, a heat storage material filled unit 50, a heat storage material 60, and a nucleating unit 70, and a controller 8. There is provided a partition wall 90 for dividing an area of the heat storage material filled unit 50. The partition wall 90 connects an upper surface and an under surface of the heat storage material filled unit 50. Note that the upper surface of the heat storage material filled unit 50 is a surface on the side of the solar cell 2, and the under surface thereof is an opposite surface. The solar cell module 20 of the solar power generator 200 tilts by θ1 in a direction vertical to gravity from an X-axis direction to a Y-axis direction. Here, it is preferable that an angle of θ1 be determined in a way such that an amount of solar radiation from the sun to the solar cell 2 becomes the maximum. The partition wall 90 is formed in a direction to prevent the heat storage material 60 from moving in a gravity direction. Furthermore, the partition wall 90 has an angle θ2 relative to the heat storage material filled unit. For example, it is preferable that the partition wall is formed in a vertical direction against the gravity direction.

The heat storage material filled unit 50 has a plurality of areas (the heat storage material filled units 50a to 50d) divided by the partition walls 90 (90ab, 90bc, 90cd). In respective areas, the heat storage materials (60a to 60d) are filled, and the nucleating units (70a to 70d) are installed. Respective areas of the heat storage material filled units 50a to 50d are separated such that the heat storage materials (60a to 60d) do not get mixed. The partition wall 90 includes a material same as the heat storage material filled unit 50. Furthermore, each of the areas 50a to 50d may be a separate container housing the heat storage material 60 and may be connected in parallel.

In FIG. 5, the partition wall 90 is formed so as to face a vertical direction of the under surface or the upper surface of the heat storage material filled unit 50 (θ2=90°). Then, in accordance with the solar cell 2, the area of the heat storage material filled unit 50 is separated so as to be quartered. This configuration is an exemplary embodiment, and a suitable embodiment may be employed from conditions of an angle of inclination θ and divided areas of the heat storage material 60 and the heat storage material filled unit 50.

The nucleating units 70a to 70d are connected to the controller 8 through a wiring L20. Accordingly, an operation instruction of the nucleating units 70a to 70d is transmitted from the controller 8 to each of the nucleating units 70a to 70d through the wiring L20.

Then, a method of operating the solar power generator 200 is described.

FIG. 6 is a flowchart illustrating a method of operating the solar power generator 200. This flowchart is recorded in advance in the controller 8, which operates each device based on a condition therein through the wiring 120 and a wiring L1.

In the flowchart in FIG. 6, first, the controller 8, measures the electric power generated by the solar cell 2 through the wiring L1 (electric power detecting: Step S021). Then, determination is performed by comparing the measured electric power (detected electric power value) and a predetermined set electric power (set electric power value) (Step S022). Then, in a case where the measured electric power is equal to or lower than the predetermined set electric power, a nucleating signal is given to ail of the nucleating units 70a to 70d through the wiring L20. Accordingly, the heat storage material 60, which has stored heat and is kept in a supercooled state, is crystallized, and latent heat is released. Note that in a case where the measured electric power is larger than the predetermined set electric power, the electric power is measured again (Step S021).

The heat storage material 60, when it reaches a melting point thereof or above, changes from solid to liquid; however, since there is a difference in density between the solid and the liquid, the solid tends to precipitate at the bottom in the gravity direction. In a case where the solar cell module 20 tilts at θ, if the heat storage material filled units 50a to 50d are communicated, the solid heat storage material 60 precipitates in a direction from 50d to 50a, and the solid heat storage material 60 is accumulated in the area 50a. In this case, in the area 50a, the heat storage material 60 is melted and becomes a high-temperature liquid, and a cell temperature of an adjacent part rises. Then, the solid heat storage material 60 remains without being melted in the area 50a, whereby the latent heat is released without supercooling. Therefore, in this embodiment, the heat storage material filled unit 50 is divided into 50a to 50d by using the partition wall 90 connecting the under surface and the upper surface of the heat storage material filled unit 50. The partition wall 90 is formed in a direction to prevent the heat storage material 60 from moving in the gravity direction. Since the heat storage materials 60 including 60a to 60d are separated from each other, the heat storage material 60d in the solid state in the above-described area 50d never moves into the area 50a. Therefore, during both daytime and evening, the heat storage material 60 of each area (50a to 50d) can uniformly cool the solar cell 2, whereby the amount of power generation can be improved.

Furthermore, it is also possible to put the heat storage materials 60a to 60d having different melting points in the heat storage material filled units 50a to 50d. The above-described problem can be further suppressed by using a latent heat storage material having a high melting point as the heat storage material 60d and by using a latent heat storage material having a low melting point as 60a.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solar power generator comprising:
a solar cell module having a solar cell, and a heat storage material filled unit configured to house a heat storage material disposed so as to thermally contact a back surface side of the solar cell, and a nucleating unit configured to release supercooling of the heat storage material; and
a controller configured to control the nucleating unit.

2. The solar power generator according to claim 1, wherein
the controller measures electric power generated by the solar cell, and
the controller compares the measured electric power and a predetermined set electric power, operates the nucleating unit, and causes nucleation of the neat storage material in a supercooled state in a case where the measured electric power is equal to or lower than the set electric power.

3. The solar power generator according to claim 1, wherein
the controller measures the time, and
the controller compares the measured time and a preset set time, operates the nucleating unit, and causes nucleation of the heat storage material in a supercooled state in a case where the measured time that has been measured is the same as or has passed the set time.

4. The solar power generator according to claim 1, wherein the solar cell module tilts relative to a vertical direction of gravity.

5. The solar power generator according to claim 1, wherein
the heat storage material filled unit includes a plurality of areas divided by a partition wall,
the partition wall connects an under surface and an upper surface of the heat storage material filled unit, and
the partition wall is formed in a direction to prevent the heat storage material from moving in a gravity direction.

6. The solar power generator according to claim 5, wherein a heat storage material having a different melting point is filled in the heat storage material filled unit divided by the partition wall.

7. The solar power generator according to claim 5, wherein the partition wall is formed in a vertical direction against the gravity direction.
